(19) United States
(12) Patent Application Publication
(10) Pub. No.: US 2016/0104403 A1
(43) Pub. Date: Apr. 14, 2016

(54) METHOD FOR VERIFYING THE OPERATION OF A BILLBOARD HAVING LIGHT-EMITTING DIODES

(71) Applicant: PRISMAFLEX INTERNATIONAL, Haute Rivoire (FR)

(72) Inventors: Pierre-Henri Bassouls, LANTIGNIE (FR); Frédéric Zadeo, ECOTAY L'OLME (FR)

(21) Appl. No.: 14/896,562

(22) PCT Filed: Jun. 19, 2014
(86) PCT No.: PCT/FR2014/051530

§ 371 Date: Dec. 7, 2015

(30) Foreign Application Priority Data
Jun. 19, 2013 (FR) 1355807

(51) Int. Cl. G09G 3/00; G01R 31/26

(52) U.S. Cl. CPC G09G 3/006; G01R 31/2635

(57) ABSTRACT

Process for verifying the operation of a display panel (1) incorporating multiple light-emitting diodes arranged in multiple subassemblies (2), in which a current of an amperage corresponding to a set level for commanding the desired illumination is applied to each light-emitting diode, characterized by the fact that it includes the following 10 steps:
apply a pre-determined common setting to each light-emitting diode subassembly (2);
measure the current consumed by each light-emitting diode subassembly (2);
determine an average value of the currents consumed by all the subassemblies (2);
trigger a malfunction alert for a subassembly (2) when the deviation in absolute value between the current consumed by the said subassembly (2) and the said average value exceeds a previously-determined threshold.

### TECHNICAL DOMAIN

The invention pertains to the domain of display panels—more precisely, light-emitting-diode illuminating panels.

More exactly, the invention concerns a process allowing one to verify the satisfactory operation of the diodes with which the panel is equipped and, more particularly, a process allowing the automatization of such a task, and its remote supervision.

### PRIOR ART

Generally speaking, panels incorporating light-emitting diodes (LEDs) are favored for the ability that they provide for displaying a practically-infinite number of images or messages, with the only limit being the storage capacity of the electronic central processing unit with which such panels are equipped. These panels also have the advantage of being able to display animated images, which makes them an increasingly-popular advertising medium.

These panels incorporate a multitude of light-emitting diodes laid out in a matrix, that can be illuminated individually according to the desired display. Diverse hardware architectures can be envisioned, notably those described in document U.S. Pat. No. 5,949,581, in which the panel incorporates a multitude of elementary arrays, each of which contains a few hundred LEDs, the arrays of which are assembled into blocks incorporating several lines and columns of arrays. Multiple blocks can then be assembled, also incorporating multiple lines and columns of blocks, to constitute the display panel.

To be able to display images at the highest possible resolution, it is necessary to individually control each diode, assigning it an instruction corresponding to the brightness desired for the diode in question. This way, each diode is controlled individually, which thus requires one control circuit for each diode.

It will be understood that, in the case of panels designed for outdoor display, the number of diodes can be extremely high—more than several hundred thousand—with, therefore, considerable risks of malfunctioning of all or part of these electronic circuits. This means that it is necessary to implement a supervision of the satisfactory operation of the panel.

To date, the technique employed for this supervision consists in filming the panel and causing the said panel to display formatted information sequences in pre-defined areas. A human operator watches a monitor showing the picture captured by the cameras filming the panel, so to thereby identify malfunctions in which the information displayed does not correspond to the pre-determined verification sequence.

It will be understood that such a method of supervision is not really satisfactory, insofar as it involves a human action.

In addition, it requires the positioning of a camera in close proximity to the panel. Such a wide-angle camera is not always easy to position at a distance sufficient to allow supervision with good picture quality. Furthermore, such a camera gives rise to a projection in relation to the surface of the panel, that is aesthetically unattractive and dimensionally disadvantageous.

Equally, the quality of the image on which the verification will be performed depends on outdoor conditions, particularly ambient lighting, so it is not always possible to perform these tests at any time.

Document US 2005/0258859 describes a process for the detection of faults in panels composed of a matrix of LEDs. This process allows one to identify an LED in the matrix that is short-circuited, because it has an excessively high leakage current. This process is not reasonably practical to apply to panels incorporating a large number of diodes, because it is necessary to perform measurements on all the lines and columns in the matrix. Additionally, this process does not allow one to identify malfunctions resulting from a disconnection of an LED—for instance, due to a fault in the soldering in the printed circuit, or due to a relative change in its electrical properties without it actually being short-circuited.

### EXPLANATION OF THE INVENTION

One aim of the invention is to enable supervision and verification of the satisfactory operation of LED panels that can be automatized and performed without human intervention.

Another aim is to achieve high-quality verification with no dependency on outdoor conditions.

Therefore, the invention addresses a process of verification of the operation of a display panel incorporating a multitude of light-emitting diodes, in which each light-emitting diode is applied a current of an amperage corresponding to a control instruction pertaining to the desired display.

According to the invention, this process includes the following steps:
apply a pre-determined common setting to each light-emitting-diode subassembly;
measure the current consumed by each light-emitting-diode subassembly;
determine an average value of the currents consumed by all the subassemblies;
trigger a malfunction alert for a subassembly when the deviation in absolute value between the current consumed by the said subassembly and the average value exceeds a previously-determined threshold.

In other words, the invention consists in undertaking a verification of the panel by checking whether the current consumed by the array of diodes corresponds with a nominal consumption.

Otherwise expressed, you apply an identical pre-determined lighting pattern to all the diode subassemblies, for which the power consumption of all the subassemblies should theoretically be practically identical. The true difference in consumption of one particular subassembly in relation to all the recorded consumptions—particularly the average value—indicates a malfunctioning of the given subassembly.

This variation in relation to the theoretical value can be in both directions. That is to say, if the consumed current is lower than the average value, it can signify that the module is improperly connected and that, therefore, it is not receiving the control instructions, or that all or part of the diodes in the array are extinguished. Conversely, if the consumed value is higher than the average value, it can signify a malfunctioning of the electronics of the diodes in question—a short circuit, for instance. One can thus detect a change in the performances of an array only if it is still operational, generating an illumination sufficiently different to that generated by the neighboring diodes for it to be visually noticeable and deteriorating the overall yield of the display.

In practice, the tests can be performed on diode subassemblies of different size, whether on an individual array or a block incorporating several arrays. The number of diodes in a subassembly can be adapted according to the overall number of diodes to be tested and the time allowed for the tests.

In practice, the panel can advantageously be multi-colored and incorporate special LEDs with several anodes, each dedicated for the emission of a separate color.

In this case, a common setting for the illumination of one single color can be applied to the light-emitting diodes of a given subassembly.

In other words, the process according to the invention allows the execution of different sequences, in which each subassembly is illuminated with just one of the elementary colors—typically red, green and blue.

Advantageously in other sequences, one can apply a common lighting setting for all the colors of the diodes, so as to obtain white illumination. Conversely, it is also possible to apply a common setting of lighting in no color, to compare whether the consumption in the case of illumination of a black image does indeed correspond with the theoretical consumption.

In practice, within a given subassembly, one can execute a succession of steps of illumination of diodes in the different colors, including white and black, by respectively illuminating all or none of the colors.

Advantageously, when the true consumptions are compared in relation to the global population of all the subassemblies, the comparison is not sensitive to the ambient lighting conditions, humidity or temperature close to or actually within the panel.

The process according to the invention can be implemented in different manners, combining hardware and software aspects within a central processing unit associated with the panel.

In other words, each panel can be autonomous for the execution of the consumption measurements, and can trigger alerts corresponding to abnormal consumptions. This central processing unit can, in particular, be connected to a central station for testing the operation of several panels, to which the alerts are thus sent, allowing supervision of an installed set of panels.

### SUMMARIZED DESCRIPTION OF THE ILLUSTRATIONS

The manner of implementation of the invention, and the resulting advantages, will come clearly to the fore in the description of the means of implementation that follows, aided by the appended illustrations, in which:

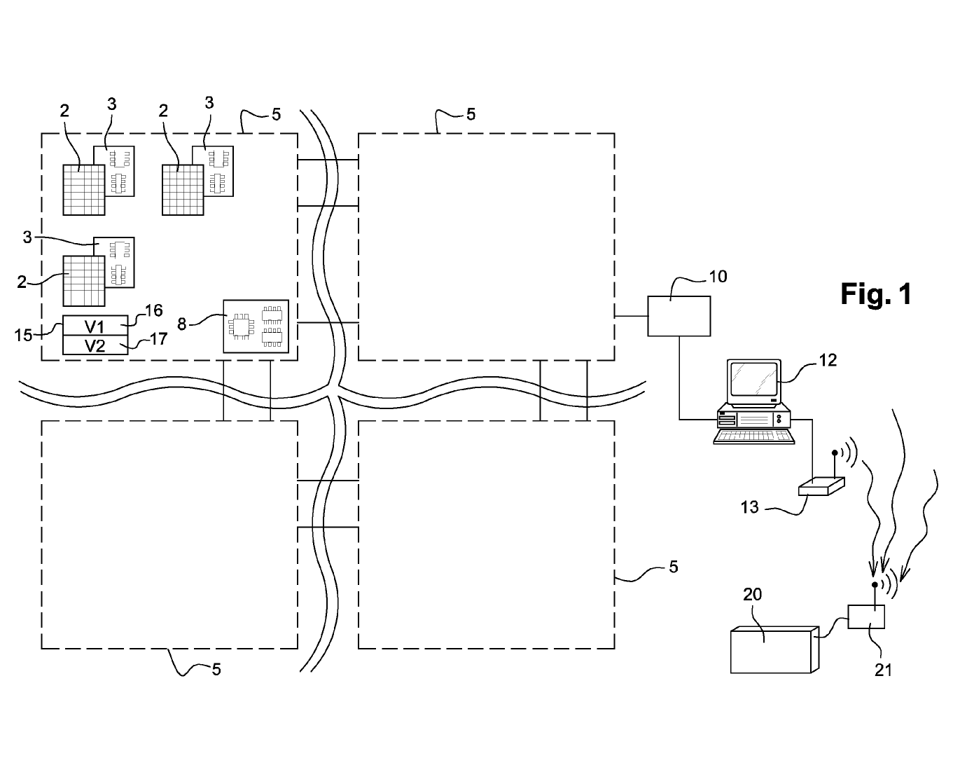

FIG. 1 is a simplified schematic showing the principal features of the invention in an LED display panel;

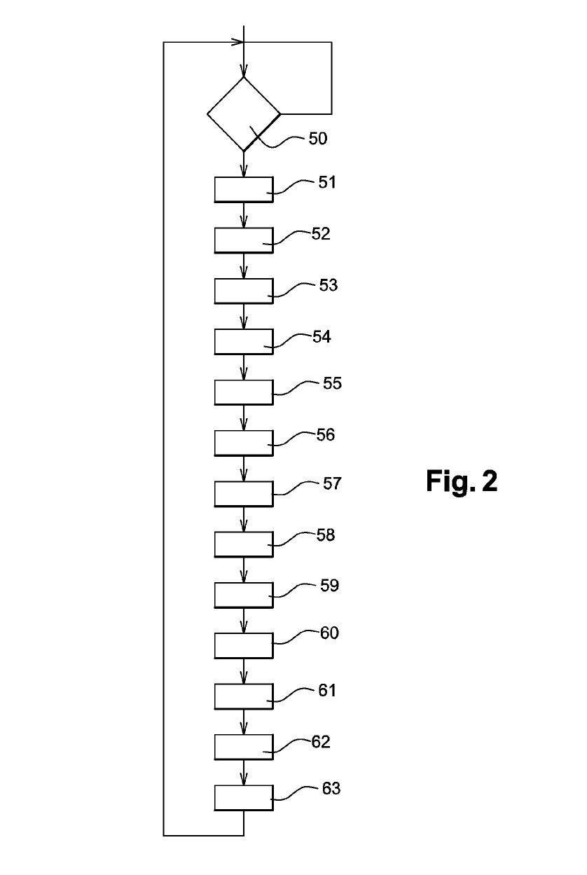

FIG. 2 is a block diagram illustrating one method of implementation of the process according to the invention;

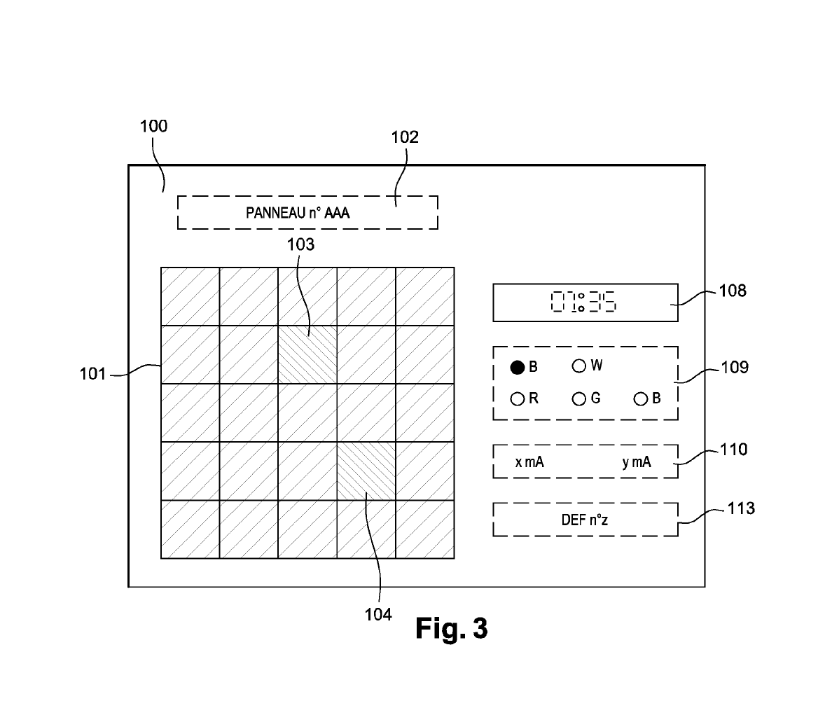

FIG. 3 is a simplified illustration of a screen displaying information pertaining to a process of the invention.

### DESCRIPTION OF ONE EXAMPLE OF IMPLEMENTATION

As already stated, the invention concerns a panel of light-emitting diodes, or LEDs. Since the invention particularly concerns a process for verifying the satisfactory operation of the panel, no detailed description is contained herein regarding aspects of the panel having no direct connection with the invention.

The mechanical construction of the panel, the composition of the various arrays of LEDs, the electronic architecture of the system of control over the illumination of the various LEDs and the management of images to be displayed will not be described in detail.

Explained in simplified terms, and as illustrated in FIG. 1, the display panel 1 includes various arrays of LEDs 2, each of which is associated with a control electronics card 3 allowing the appropriate illumination of the various diodes. These arrays 2 incorporate a number of diodes that depends on the desired resolution of the panel, and the invention can be implemented regardless of the number of diodes present in an array.

The various arrays 2 are assembled in blocks 5. Each block 5 incorporates a certain number of arrays 2 arranged in lines and columns. The panel 1 incorporates as many block modules 5 as necessary to constitute the display area.

In practice, each block 5 incorporates a common electronics card 8. This card 8 receives data from a central processing unit 10 that acts as a controller and sends the various blocks 5 data concerning the images to be displayed.

The various arrays 2 can be connected to the card 8 either via a common bus, which might be looped to provide redundancy, or via individual links, without falling outside the scope of the invention.

Similarly, the various cards 8 managing the operation of each block 5 can be connected to the controller 10 via a common bus forming a network between the blocks, or can be connected directly.

The controller 10 is itself connected to a central processing unit 12 that provides the overall management of the panel, particularly the load of different images displayed by means of a link to the transmission network by any appropriate means, notably via a cable-connected or wireless modem 13 of GSM or analog type.

From the viewpoint of electronics, each block 5 incorporates a power supply device 15 that powers the various cards 3, 8 present in the arrays and blocks. In the case of a color display panel, it is possible for the diodes to be powered at nominal voltages that depend on their color. Thus, the power supply device will incorporate an equal number of sub-modules able to supply the appropriate voltages for controlling each type of diode. As an example—which is illustrated—one module 16 supplies a voltage of 5 Volts, which is intended to power green and blue diodes, while a second module 17 supplies a voltage of 3.3 Volts intended to power red diodes.

In variants that are not illustrated, the power supply device can be common to multiple blocks, and can supply power to each of the blocks via different types of architecture, without falling outside the scope of the invention.

According to the invention, each electronics card 3 associated with an array 2 is equipped with a circuit allowing the measurement of the current consumed by the array, for each of the power voltages supplied by the power modules 16, 17.

This information can be carried to the management card 8 common to a block 5, and then routed to the controller 10 and, thus, the management station 12.

According to the invention, the panel is equipped with means of detecting its satisfactory operation. In the form illustrated, these means are in software form and are located in the central processing unit 12 handling the overall management of the panel.

More precisely, this software processes the consumption data from each of the arrays, which arrives via cards 8 common to the block and the controller 10.

More precisely, this software implements the following operations, which are all shown in the block diagram in FIG. 2.

Accordingly, at regular intervals governed by a configuration adjustable according to the panel's management method, it is decided at step 50 to commence an operation of verification of satisfactory operation. At step 51, an instruction is sent to each of the arrays to illuminate all its diodes in white, namely to power every diode in the panel with its three red, blue and green components.

In practice, the instruction sent during the test corresponds to illumination at maximum brightness, but it is also possible to send an instruction for intermediate brightness, to check whether the power consumed is too great.

At step 52, each of the arrays measures the current consumed for the two power voltages, insofar as, firstly, the blue and green diodes and, secondly, the red diodes are simultaneously powered to generate white light. The data about the two amperages consumed is sent to the central processing unit 12.

In the next step 53, an instruction for illumination of a red image is sent to each of the arrays.

In the next step, 54, each of the arrays measures the amperage measured for the power voltage of 3.3 Volts, and sends this information to the central processing unit 12.

In the next step, 55, an instruction for illumination of a green image is sent to each of the arrays.

In the next step, 56, each array measures the current consumed for the 5-Volt power voltage, and sends this information to the central processing unit 12, via the card common 10 to the block 8.

The same operations are performed at steps 57 and 58, with an illumination instruction and a blue image.

Subsequently, in step 59, an instruction for illumination of a black image is sent, corresponding to a null amperage imposed in all the diodes of the arrays 2 in step 60. The measurement of the currents consumed at the two power supply voltages is performed by each of the arrays, and is sent—as previously—to the central processing unit 12.

In a subsequent step 61, the average value and the standard deviation of each of the measurements is calculated for each of the instructions sent, namely for the five image colors displayed.

In a subsequent stage 62, each of the five measurements performed for each array is compared with the average value and the standard deviation calculated previously. The test procedure can be performed in any order, for the 5 LED colors (white, red, green, blue and black), without falling outside the scope of the invention.

If the measurements for a particular array differ excessively from the calculated averages, an alert can be generated for the array in question. In certain cases, it can be decided only to perform the test for a limited number of test colors, or even just one, depending on the panel's application, while preserving an effective failure detection rate.

The abnormal character of the measurement can be established in various manners, based on traditional statistical methods, in relation to the average and standard deviation, or in relation to a threshold linked to the average value, for example, of around 20%, without falling outside the scope of the invention. These thresholds can be adapted to the type of panel and the operational conditions. They can differ according to the color of the image, and can be above or below the average value.

The fault information is then sent, in step 63, to a centralized management system, represented by the central processing unit 20 in FIG. 1. This central processing unit, which incorporates means of connection 21, is able to receive information from various panels, which are managed centrally.

Different types of fault can thus be detected. We can notably cite the case in which an entire array remains extinguished regardless of the instruction sent, signifying a general failure of the electronics associated with the array, or an electrical disconnection. It is also possible to detect an inability to illuminate one of the three color components. More-specific faults can also be detected, notably, for instance, complete or partial non-operation, namely for one, two or three of the colors of each diode.

If the number of defective diodes within the array is significant, the measurement performed will also be identifiable.

It is also possible to detect malfunctions in which the brightness of all or part of the diodes of an array is lower than the set level, corresponding to premature aging of the array, for example.

It is also possible to detect faults resulting in random illumination of the diodes of an array, or illumination having no relation to the setting applied.

To facilitate fault detection, the control station 20 can give access to a range of information items via a screen, of which an example is illustrated in FIG. 3. One such screen 100 includes a first area 101 showing a mapping of the panel, in which a grid individually identifies each of the arrays, stating the defective arrays 103, 104 by means of a color code. The panel in question is identified by an area 102, with all the necessary information items to allow its identification and location.

As an example, the screen shown in FIG. 3 shows, in a special area 108, the time at which the test was performed. The area 109 shows which test—shown in the screen—corresponds to which displayed color instruction.

Area 110 shows the amperage measured for each of the power supply voltages, compared with the calculated average amperage. One area 113 shows a fault type. This type of fault can correspond to a pre-programmed classification stating the supposed fault type, which can require a simple wiring verification or a probable replacement of the array considered to be defective.

Of course, this is one particular example, and many other information items can be displayed in one way or another.

It comes to the fore, from the above explanations, that the process according to the invention enables effective supervision of LED panels without the addition of hardware external to the panel. This supervision can be performed in a totally automatized manner, as well as independently of the weather conditions, since faults are identified in relation to average values for all the arrays. Another notable advantage of the invention is that one is able to identify sporadic malfunctions that are not easily identifiable by a camera system performing observations at given moments.

1/ Process for verifying the operation of a display panel (1) incorporating multiple light-emitting diodes arranged in multiple subassemblies (2), in which a current of an amperage corresponding to a set level for commanding the desired display is applied to each light-emitting diode, characterized by the fact that it includes the following steps:
apply a pre-determined common setting to each light-emitting diode subassembly (2);
measure the current consumed by each light-emitting diode subassembly (2);
determine an average value of the currents consumed by all the subassemblies (2);
trigger a malfunction alert for a subassembly (2) when the deviation in absolute value between the current consumed by the said subassembly (2) and the said average value exceeds a previously-determined threshold.

2/ Process according to claim 1, in which the light-emitting diodes have multiple anodes, with each individual anode being dedicated for the emission of a separate color, and to which a common setting for illumination in a single color is applied to the light-emitting diodes of a subassembly (2).

3/ Process according to claim 1, in which the light-emitting diodes have multiple anodes, with each individual anode being dedicated for the emission of a separate color, and in which a common setting for simultaneous illumination of all colors is applied to the light-emitting diodes of a subassembly (2).

4/ Process according to claim 1, in which the light-emitting diodes have multiple anodes, with each anode being dedicated for the emission of a separate color, and to which a common setting for simultaneous illumination of no color is applied to the light-emitting diodes of a subassembly (2).

5/ Process according to claim 2, 3 or 4, in which the steps of illumination of the light-emitting diodes of a subassembly and of measurement of the current consumed are sequenced in succession.

6/ Process according to claim 1, in which the alerts are relayed to a central station for the verification of operation of multiple display panels.

7/ Display panel incorporating multiple light-emitting diodes, and equipped with hardware and/or software designed to implement the process in accordance with one of claims 1 to 6.

8/ Display panel in accordance with claim 7, in which the light-emitting diodes are grouped within arrays (2) in which the light-emitting diodes are arranged in a matrix, with the said arrays themselves being arranged in matrix form within blocks (5), and with the said blocks themselves being arranged in matrix form within the panel's framework.
